(19) United States
(12) Patent Application Publication
(10) Pub. No.: US 2023/0200262 A1
(43) Pub. Date: Jun. 22, 2023

(54) ASYMMETRIC DOUBLE DOLAN BRIDGE

(71) Applicant: INTERNATIONAL BUSINESS MACHINES CORPORATION, Armonk, NY (US)

(72) Inventors: Leonidas Ernesto Ocola, Wappingers Falls, NY (US); Vivekananda P. Adiga, Ossining, NY (US); Jeng-Bang Yau, Yorktown Heights, NY (US)

(21) Appl. No.: 17/558,552

(22) Filed: Dec. 21, 2021

(51) Int. Cl. H01L 39/02; H01L 39/22; H01L 39/24

(52) U.S. Cl. CPC H01L 39/025; H01L 39/223; H01L 39/2493; G06N 10/40

(57) ABSTRACT

A double Dolan Bridge structure includes two Dolan Bridges arranged side-by-side to form a Josephson Junction. Each Dolan Bridge includes a substrate, and a triple stack resist configuration including three layers of material arranged on the substrate. An asymmetrically arranged junction including at least three metallic layers is arranged on the substrate in a stack having no more than two of the least three metallic stacked on each other.

### BACKGROUND

### Technical Field

The present disclosure generally relates to qubit manufacturing for quantum computing, and more particularly, to Josephson Junctions (JJ) and Dolan Bridges in which a quadrupole (also known as “pizza”) qubit is fabricated.

### Description of the Related Art

The fabrication of Josephson Junctions (JJs) can use techniques that include a shadow mask lithographical approach. For example, a triple stack resist configuration is typically used instead of a standard bilayer resist. An evaporation mask is suspended above a substrate to apply layers of material on the substrate. Depending on an evaporation angle, the shadow image is projected onto different positions of the substrate. By choosing an angle for each material to be deposited, adjacent overlays can be projected in the same spot to create an overlay of thin films with a well-defined geometry between a first conductive layer and a second conducting layer. The evaporation mask is formed from layered material, such as three layers of resist, and has two openings instead of one normally used for a standard Dolan bridges. Other materials besides resists (such as inorganic materials) can be used. After evaporation, the shadow mask is removed leaving behind the deposited metal.

### SUMMARY

In one embodiment, a double Dolan Bridge structure includes two Dolan Bridges arranged side-by-side to form a Josephson Junction. Each Dolan Bridge includes a substrate, and a triple stack resist configuration including three layers of material arranged on the substrate that are used as shadow materials. An asymmetrically arranged junction including at least three metallic layers arranged on the substrate in which no more than two of the least three metallic layers are stacked on each other.

In an embodiment, a step coverage of the junction is a single layer. The three layers of materials can be resists and/or inorganic materials.

In an embodiment, the Josephson Junction includes a cross type Josephson Junction.

In an embodiment, the Josephson Junction includes a second conductor deposited on the substrate in a longitudinal direction.

In an embodiment, a first portion of the first conductor is deposited on the substrate in a left-to-right direction relative to the longitudinal direction of the second conductor, and a second portion of the first conductor is deposited on the substrate in a right-to-left direction relative to the longitudinal direction of the second conductor.

In an embodiment, wherein the cross type Josephson Junction includes a first conductor arranged on the substrate, and a second conductor having a first portion and a second portion deposited on the substrate. A dielectric layer is arranged between the first conductor and the second conductor. The first portion and the second portion of the second conductor are each deposited on the substrate at a different distance from the first conductor.

In an embodiment, a distance between the first conductor and the first portion of the second conductor is less than a distance between the first conductor and the portion of the second conductor.

In an embodiment, the cross type Josephson Junction includes a first conductor, and a second conductor having a first portion and a second portion deposited on the substrate at an angle relative to the first conductor. A dielectric layer is arranged between the first conductor and the second conductor. The first portion and the second portion of the second conductor are each deposited on the substrate at an asymmetrical angle.

In an embodiment, the first conductor and the second conductor are constructed of aluminium.

In an embodiment, the three layers of material of the triple stack configuration respectively include one of a methyl methacrylate (MMA), a polymethyl methacrylate (PMMA), or a lift off resist (LOR).

In one embodiment, a method of fabricating an asymmetric double Dolan Bridge, includes manufacturing two Dolan Bridges, wherein each Dolan bridge is manufactured by providing a substrate, and arranging on the substrate a triple stack configuration including three layers of material. An asymmetrically arranged junction includes at least three metallic layers arranged on the substrate. No more than two of the least three metallic layers are stacked on each other. The two Dolan Bridges are arranged side-by-side to form a Josephson Junction.

In an embodiment, the method further includes fabricating the Josephson Junction by depositing a second conductor on the substrate in a longitudinal direction, depositing a first portion of the first conductor on the substrate in a left-to-right direction relative to the longitudinal direction of the second conductor, and depositing a second portion of the first conductor on the substrate in a right-to-left direction relative to the longitudinal direction of the second conductor.

In an embodiment, the method further includes depositing the first conductor and the second conductor using an evaporation mask suspended above the substrate.

In an embodiment, the three layers of material of the triple stack configuration arranged on the substrate include resists and/or an inorganic layer.

In an embodiment, a method of manufacturing an asymmetric Double Dolan bridge includes depositing three layers of material on a substrate with an evaporation mask suspended above the substrate. A first conductor and a second conductor are disposed on the substrate to form quadrupole qubit. The first conductor is disposed on the substrate by applying a first portion of the first conductor on the substrate in a left-to-right direction, and applying a second portion of the first conductor on the subject in a right-to-left direction.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A is an overview illustrating CAD designs of a symmetric junction of a symmetric Double Dolan Bridge from a related pending patent application “Improved Lithography for shadow-evaporated Josephson Junctions” by C. Rettner et al. filed 30 Jul. 2021, application EP2021/071429, and an asymmetric junction of a Double Dolan Bridge consistent with an illustrative embodiment.

FIG. 1B illustrates the symmetric CAD design and a photo of the junction of the Double Dolan Bridge consistent with an illustrative embodiment.

FIG. 1C illustrates an asymmetric CAD design of the Double Dolan Bridge consistent with an illustrative embodiment.

FIG. 2A illustrates a first portion of a method of constructing of a symmetric Double Dolan bridge using a triple resist stack, consistent with an illustrative embodiment.

FIG. 2B illustrates a second portion of a method of constructing of a symmetric Double Dolan bridge using a triple resist stack, consistent with an illustrative embodiment..

FIG. 3A illustrates a first portion of the construction of an asymmetric Double Dolan bridge, consistent with an illustrative embodiment.

FIG. 3B illustrates a second portion of the construction of an asymmetric Double Dolan bridge, consistent with an illustrative embodiment.

FIG. 4 is an image of a symmetric construction of a Josephson Junction.

FIG. 5 is an image of an asymmetric construction of a Josephson Junction Double Dolan Bridge consistent with an illustrative embodiment.

FIG. 6 shows various quadrupole junctions designs, consistent with an illustrative embodiment.

FIG. 7 is a flowchart illustrating a method of fabricating an asymmetric construction of a Josephson Junction Double Dolan Bridge, consistent with an illustrative embodiment.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the term “longitudinal direction” refers to a direction of a surface of a substrate. In addition, the terms “right-to-left” and “left-to-right” refer to lateral directions on the surface of the substrate relative to the longitudinal direction.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

As used herein, the term “Josephson Junction” generally refers to a junction having two superconductors separated by a thin insulating barrier.

As used herein, the term “Dolan Bridge” refers to a lithographically patterned Josephson Junction that has multiple layers of material. Shadow masking is one technique that can be employed as described herein to provide an enhanced junction structure. A first lead may be formed on a substrate, and a second lead formed on the first lead with a dielectric layer arranged between the first and second leads. The angle of deposition of the second lead formed on the substrate is different than the first lead. For example the second lead can be normal to the first lead.

According to an embodiment of the present disclosure, a Dolan bridge structure is fabricated with three depositions of metal (e.g., a triple stack) that are positioned to enhance the Dolan Bridge structure. In addition, three levels of resist can be employed, which provides additional benefits over the commonly-used two levels of resist.

According to aspect of the present disclosure, a Double Dolan bridge structure includes two Dolan bridges that are arranged side-by-side to create a novel Josephson Junction. A method of fabrication as discussed herein overcomes some difficulties regarding interfacing and coverage of various materials being deposited to form the Dolan Bridge Josephson Junction.

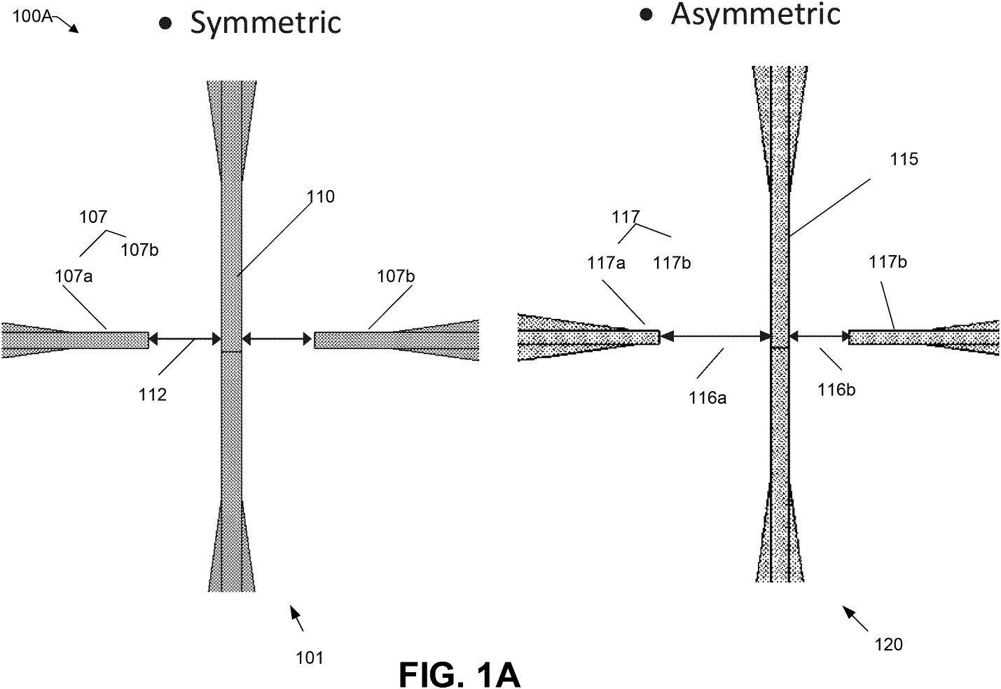

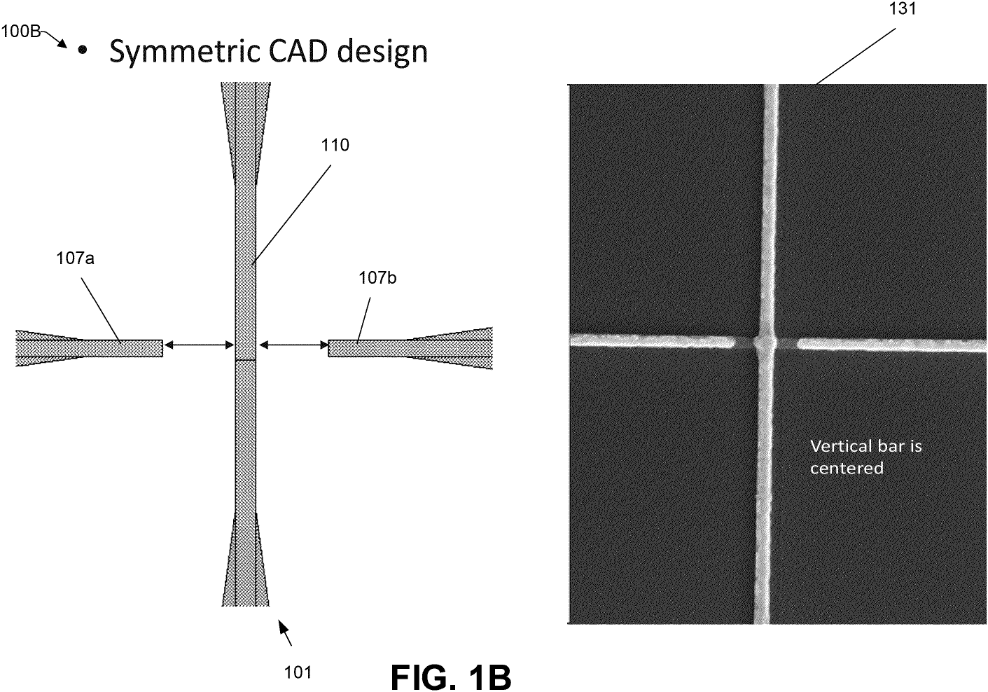

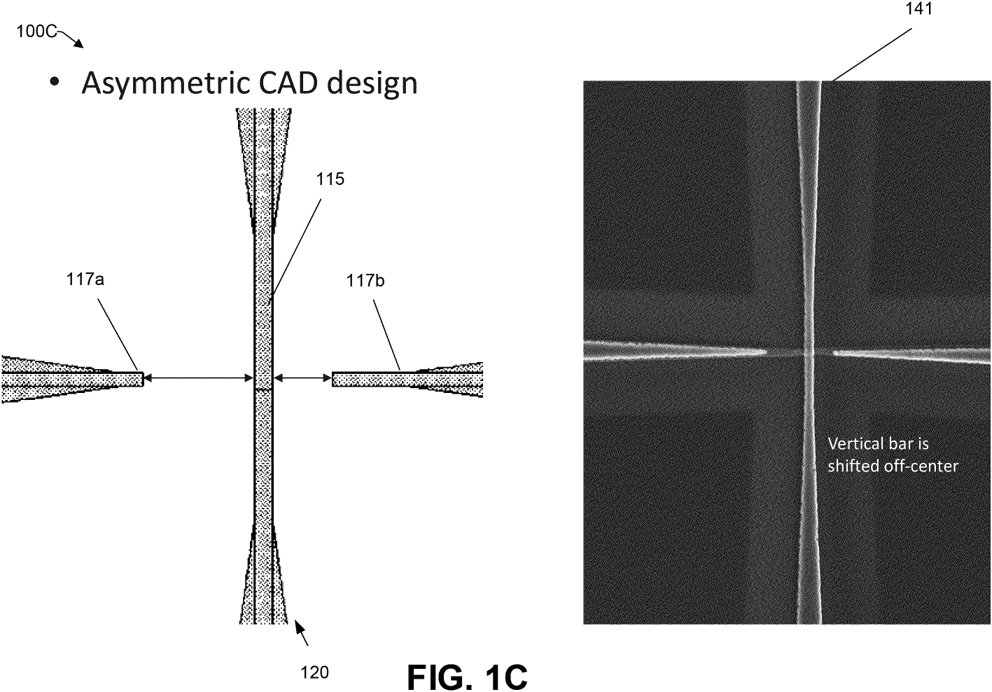

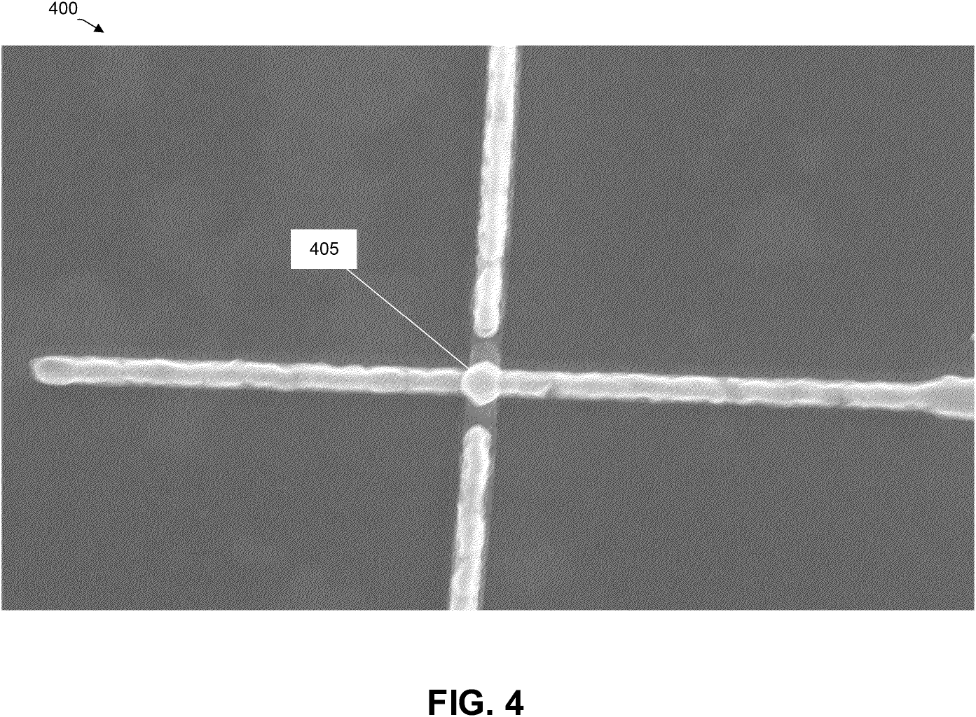

FIG. 1A is an overview 100a illustrating CAD designs of a symmetric junction 101 of a Dolan Bridge and (b) an asymmetric junction 120 of a Double Dolan Bridge, consistent with an illustrative embodiment. In a symmetric approach, there is shown a top view of a symmetric junction 101 having a first conductor 110 and a second conductor 107. Two portions of the second conductor 107 are disposed on a substrate at an angle relative to a normal, such as the position of the first conductor 110. FIG. 1B shows views 100B of the symmetric CAD design 101 and an actual photo of the junction 131 consistent with an illustrative embodiment. FIG. 1C shows views 100C of the asymmetric CAD design 120 of FIG. 1A and an actual photo 141 of the junction consistent with an illustrative embodiment. Referring to FIG. 1A, a dielectric layer (not shown) is arranged between the first conductor 110 and the second conductor 107. The portions 107a, 107b of the second conductor 107 are deposited on the substrate at a symmetrical distance 112 from the first conductor 110. The portions 107a, 107b of the second conductor 107 typically connect under the first conductor 110. FIG. 4 illustrates some of the issues associated with a symmetrical junction such as the CAD design image of the junction 101 shown in FIG. 1A. The symmetrical junction 400 shown in FIG. 4, which is constructed using a metal deposition using a bilayer process, has a knob 405. Disruptions to the junction from lineage roughness, and metal deposition artifacts can result from the fabrication of the symmetrical junction 101 of the type shown in FIGS. 1A and 1B.

In one embodiment of the present disclosure, an asymmetric junction 120 has a first conductor 115 and a second conductor 117. The second conductor has two portions 117a, 117b deposited on a substrate at an angle relative to each other. A dielectric layer is arranged therebetween. It is shown in FIG. 1B that the distance 116a, 116b of the first and second portions 117a, 117b of the second conductor 117 are deposited at an asymmetrical distance from the first conductor 115. More particularly, the distance between the first conductor 115 and the first portion 117a of the second conductor 117 is less than the distance between the first conductor 115 and the portion 117b of the second conductor 117.

Additional features of the method and device of the present disclosure are disclosed herein.

### Example Embodiments

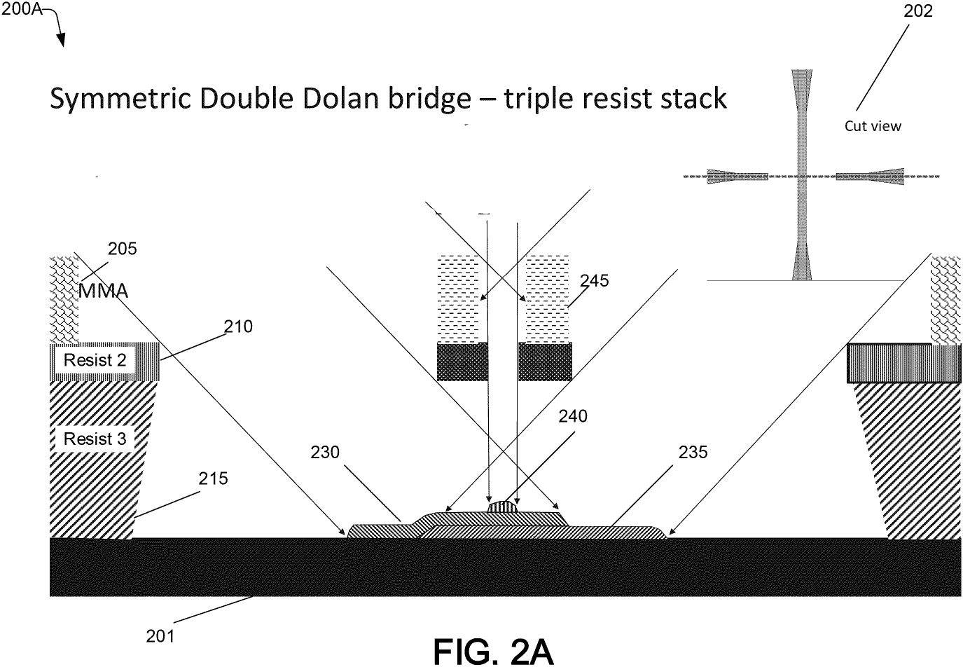

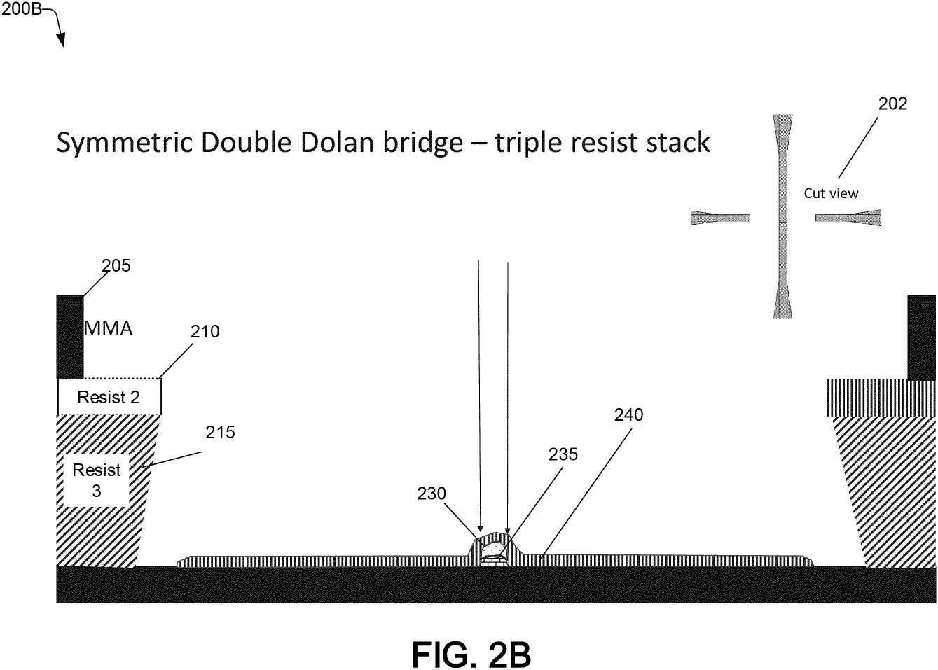

FIG. 2A illustrates a first portion 200A of a method of constructing a symmetric Double Dolan bridge using a triple resist stack, consistent with an illustrative embodiment. There is shown three resist layers of resist. The first layer resist layer 205 can be constructed of methyl methacrylate (MMA). The second resist layer 210 can be constructed of polymethyl methacrylate (PMMA). The third resist layer 215 may be constructed of a lift off resist (LOR). A cut view 202 shows two portions of a deposition of a first conductor and a deposition of a second conductor that intersect to form a junction.

With continued reference to FIG. 2, the junction structure shows a substrate 201 having two “aluminum-1” depositions 230, 235 that are stacked and an “aluminum-2” deposition 240 on top of the aluminum-1 depositions 230, 235 to form a triple stack. The aluminum-deposition 240 can be arranged in a longitudinal (e.g., north-south position) (see the cut view 202 in FIG. 2). The aluminum-1 depositions 230, 235 are applied in substantially an east-west, west-east deposition, and do not touch. The PMMA feature (resist 2) is used for the aluminum-2 deposition 240. The MMA barrier blocks the aluminum-2 deposition. An evaporation mask 245 is a suspended bridge having two layers of resist. The evaporation masks 245 (345) are suspended above the substrate 201 to provide a deposition of aluminum-2 240 to form the junction. Through selection of an angle for each material to be deposited, adjacent openings in the mask can be projected on a same spot, creating an overlay of the two thin films with a well-defined geometry between the first conducting layer and the second conducting layer.

FIG. 2B illustrates a second portion of a method of constructing of a symmetric Double Dolan bridge using a triple resist stack from a related pending application. As can be seen, there is a double layer of aluminum (e.g., the aluminum depositions 230, 235) and the aluminum-2 240 is deposited over the two aluminum-1 layers, 235, 240. This arrangement involves a step coverage of the aluminum-2 240 over the two layers of aluminum-1 230, 235, and may result in the undesirable formation of a knob (see knob 405 in FIG. 4), artifacts, and/or linear roughness. Thus, there can be a disruption in the operation of the junction because of the undesirable formations.

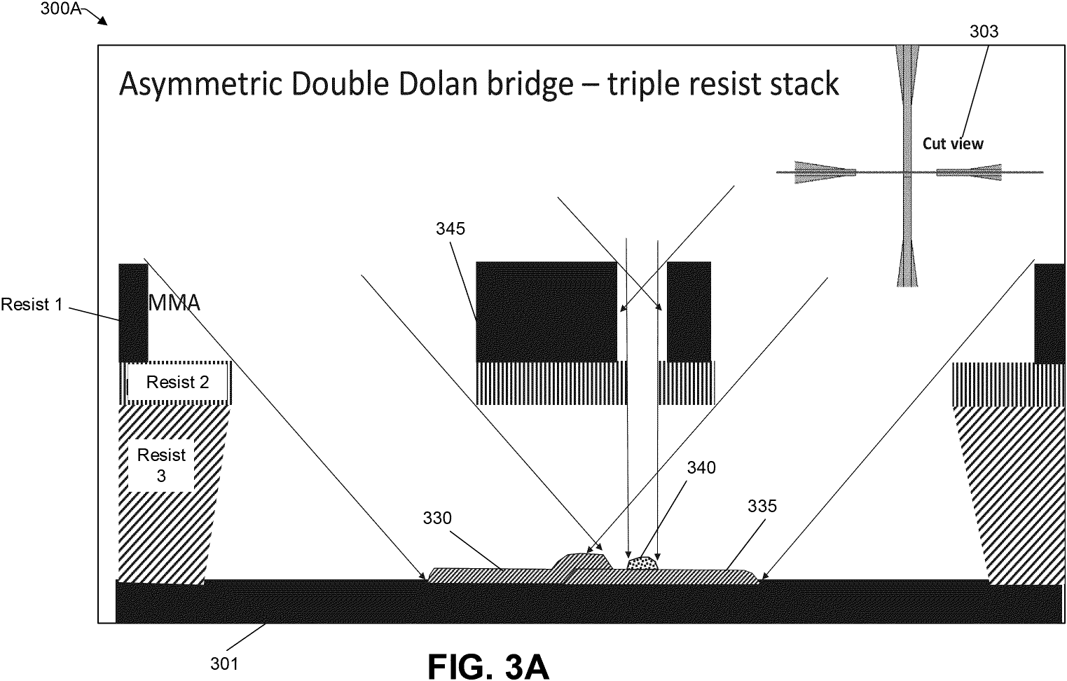

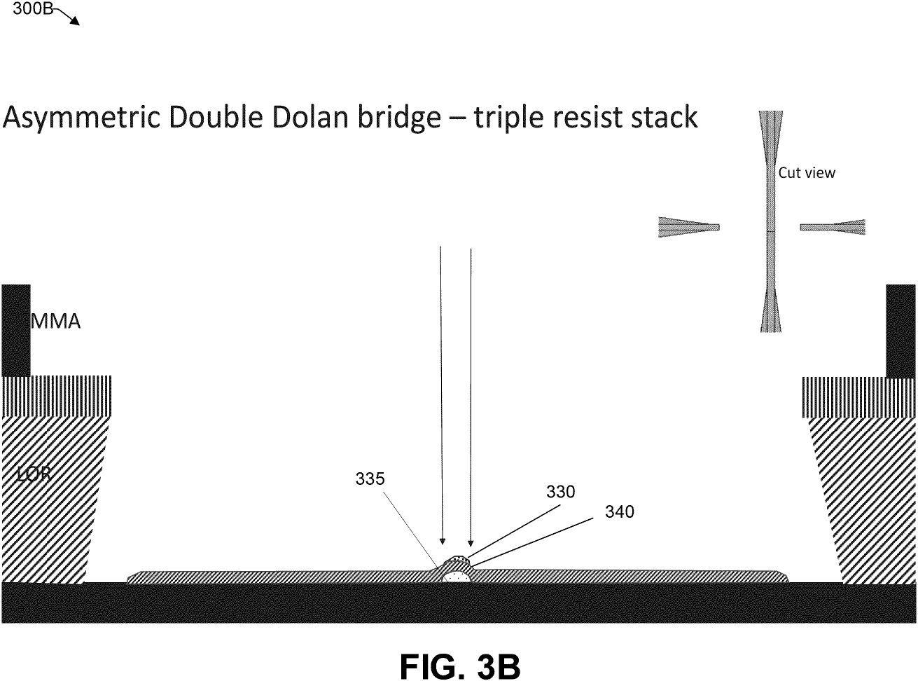

FIG. 3A illustrates a first portion of the construction of an asymmetric Double Dolan bridge, consistent with an illustrative embodiment. The asymmetric Double Dolan bridge utilizes a triple resist stack that is somewhat similar the description regarding FIGS. 2A and 2B. There may be three resist layers (a resist 1 (305), a resist 2 (310) and a resist 3 (315)) that are stacked on a substrate 301. In one embodiment, there are two conductive layers deposited on the substrate to form the junction. An evaporation mask 345 is a suspended bridge of resist above the substrate and the shadow image of the mask is projected onto different positions of the substrate 301. The layers of resist of the evaporation mask on opposite side of the opening to project the aluminum-2 340 are asymmetrical. In other words, the location of the evaporation mask 345 is shifted from the center point of the cut view 303. The cut view 303 shows an asymmetric arrangement of a first conductor having two portions (e.g., aluminum 1 (330, 335)) relative to the second conductor 340.

According to an aspect of the disclosure, the asymmetrical deposition of a first portion of the aluminum-1 conductor 330 and a second portion of the aluminum-1 conductor 335 has a reduced overlap that permits the deposition of the aluminum-2 340 on one portion of the aluminum-1 conductor 335 as shown in FIG. 3A, rather than on two portions of the aluminum-1 conductor 230, 235 shown in FIG. 2A. Accordingly, the junction shown in FIGS. 3A and 3B has a reduced step coverage of one layer (e.g., as opposed to two-layer step coverage shown in FIGS. 2A, 2B). To reiterate, step coverage over one layer in the asymmetrical construction according to the present embodiment is an improvement over two-layer step coverage in the symmetrical construction such as shown in FIGS. 2A, 2B.

FIG. 3B illustrates a second portion of the construction of an asymmetric Double Dolan bridge, consistent with an illustrative embodiment. The deposition of the aluminum-2 340 on the first portion the aluminum-1 335 results in a junction having a reduced height as compared the junction shown in FIG. 2B. The asymmetrical deposition of the first portion of aluminum-1 330 and the second portion of aluminum-1 335 results in a reduction or elimination of issues with the formation of knobs, and the structure exhibits improved metal line edge roughness and improved step coverage.

FIG. 4 is an image of a symmetric construction of a Josephson Junction. As discussed above in the overview, the symmetrical junction 400 shown in FIG. 4 has a knob 405 that formed from the junction fabrication. Disruptions to the junction from lineage roughness, and metal deposition artifacts can result during the fabrication process of a symmetrical junction.

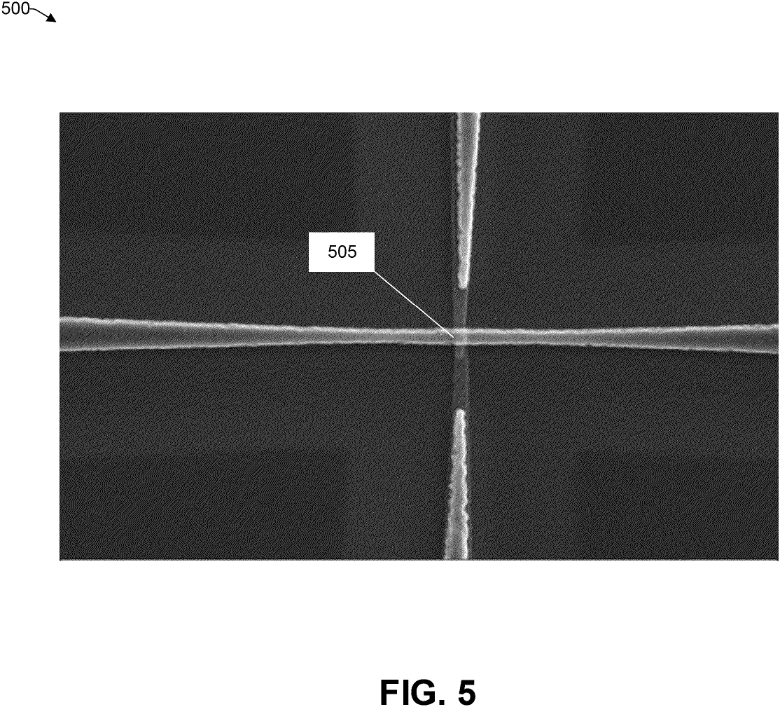

FIG. 5 is an image of an asymmetric construction of a Josephson Junction Double Dolan Bridge 500, consistent with an illustrative embodiment. The junction 505 shown in FIG. 5 shows a smooth construction without knobs, artifacts and line roughness such as in the junction 405 shown in FIG. 4. The construction of the junction 505 is based on an asymmetric CAD design 120 such as shown in FIG. 1C.

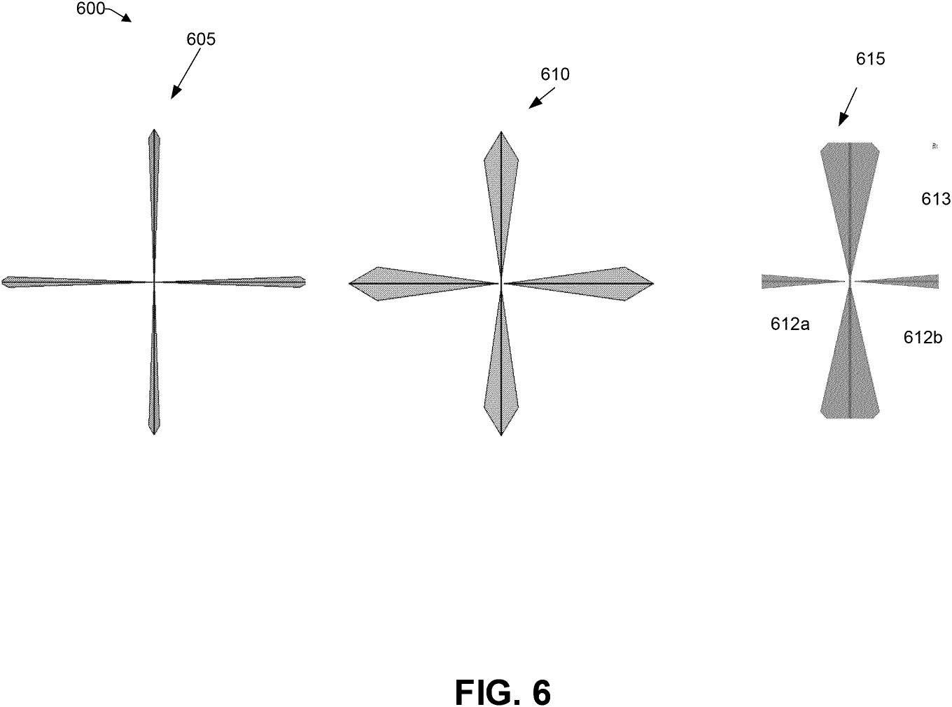

FIG. 6 shows various quadrupole junctions designs, consistent with an illustrative embodiment. It is to be understood that the quadrupole junctions are provided in FIG. 6 for illustrative purposes, and the appended claims are not limited to the designs shown in FIG. 6. It can be seen that the “pizza” shape is relatively narrow in the junction 605, where there is a medium width for the junction 610, and the junction 615 has the widest width. In this example one conductor 613 is arranged in a longitudinal (e.g., North-South direction), and the second conductor 612a, 612b is deposited in a respective left-to-right, right-to-left directions (e.g., west to east, east to west) relative to the longitudinal direction of the conductor 613. The features of the respective conductors 612a, 612b will extend underneath the longitudinal (North-South) facing conductor 613 to form the junction. In addition, the left-to-right, right-to-left construction of a junction such as shown in FIG. 6 improves the deposition of the conductor (e.g., aluminum 1) onto niobium pads that are used with such structures, and have a thickness of about 200 nm.

### Example Process

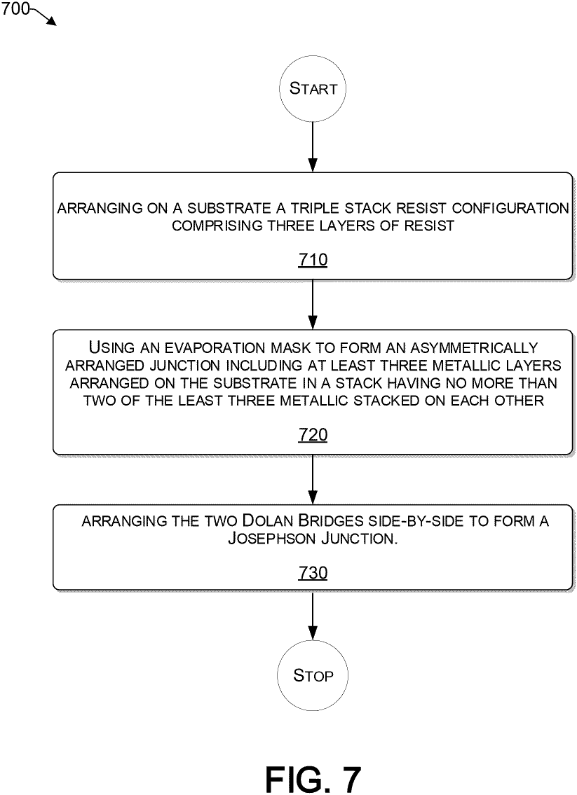

With the foregoing overview of the example architecture, it may be helpful now to consider a high-level discussion of an example process. To that end, FIG. 7 is a flowchart illustrating a method of fabricating an asymmetric construction of a Josephson Junction Double Dolan Bridge, consistent with an illustrative embodiment.

FIG. 7 is shown as a collection of blocks, in a logical order, which represents a sequence of operations that can be implemented in hardware, software, or a combination thereof. In the context of software, the blocks represent computer-executable instructions that, when executed by one or more processors, perform the recited operations. Generally, computer-executable instructions may include routines, programs, objects, components, data structures, and the like that perform functions or implement abstract data types. In each process, the order in which the operations are described is not intended to be construed as a limitation, and any number of the described blocks can be combined in any order and/or performed in parallel to implement the process.

At operation 710, two Dolan Bridges are manufactured by arranging on a substrate a triple stack resist configuration including three layers of resist The Dolan bridges according to the present disclosure can use MMA, PMMA and LOR as resists. However, the present disclosure is not limited to these materials. Other resist combinations of materials can be used for a Dolan Bridge can be used. It is also within the scope of the present disclosure to include an inorganic layer such as a hard mask as well.

At operation 720, an asymmetrically arranged junction is formed on the substrate with an evaporation mask. Three metallic layers (e.g., first and second portions of a first conductor, and a second conductor) are formed on the substrate. The construction is asymmetrical as only two of the layers are stacked to form a single layer step.

At operation 730 the two Dolan Bridges are arranged side-by-side to from a Josephson Junction. In one embodiment, the method then ends.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

The flowchart, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A double Dolan Bridge structure, comprising:
two Dolan Bridges arranged side-by-side to form a Josephson Junction, each Dolan Bridge comprising:
a substrate;
a triple stack configuration comprising three layers of materials arranged on the substrate that are used as shadow masks; and
an asymmetrically arranged junction including at least three metallic layers arranged on the substrate in a stack having no more than two of the least three metallic stacked on each other.

2. The double Dolan Bridge of claim 1, wherein a step coverage of the junction is a single layer, and wherein the three layers of materials comprise resists and/or inorganic materials.

3. The double Dolan Bridge of claim 1, wherein the Josephson Junction comprises a cross type Josephson Junction.

4. The double Dolan Bridge of claim 1, wherein:
the Josephson Junction includes a second conductor deposited on a surface of the substrate in a longitudinal direction;
a first portion of the first conductor is deposited on the substrate in a right-to-left direction relative to the longitudinal directional of the second conductor; and
a second portion of the first conductor is deposited on the substrate in a left-to-right direction relative to the longitudinal directional of the second conductor.

5. The double Dolan Bridge of claim 1, wherein the cross type Josephson Junction comprises:
a first conductor arranged on the substrate;
a second conductor having a first portion and a second portion deposited on the substrate; and
a dielectric layer arranged between the first conductor and the second conductor,
wherein the first portion and the second portion of the second conductor are each deposited on the substrate at a different distance from the first conductor.

6. The double Dolan Bridge of claim 5, wherein a distance between the first conductor and the first portion of the second conductor is less than a distance between the first conductor and the portion of the second conductor.

7. The double Dolan Bridge of claim 1, wherein the cross type Josephson Junction comprises:
a first conductor;
a second conductor having a first portion and a second portion deposited on the substrate at an angle relative to the first conductor; and
a dielectric layer arranged between the first conductor and the second conductor;
wherein the angle that each of the first portion and the second portion of the second conductor are respectively deposited on the substrate relative to the first conductor is asymmetrical.

8. The double Dolan Bridge of claim 7, wherein the first conductor and the second conductor are constructed of aluminium.

9. The double Dolan Bridge of claim 7, wherein the three layers of material of the triple stack respectively comprise one of a methyl methacrylate (MMA), a polymethyl methacrylate (PMMA), or a lift off resist (LOR).

10. A method of fabricating an asymmetric double Dolan Bridge, the method comprising:
manufacturing two Dolan Bridges, each Dolan bridge manufactured by:
arranging, on a substrate, a triple stack configuration comprising three layers of material;
forming with an evaporation mask an asymmetrically arranged junction including at least three metallic layers arranged on the substrate in a stack having no more than two of the least three metallic stacked on each other; and
arranging the two Dolan Bridges side-by-side to form a Josephson Junction.

11. The method according to claim 10, further comprising fabricating the Josephson Junction by:
depositing a second conductor on the substrate in a longitudinal direction;
depositing a first portion of the first conductor on the substrate in a right-to-left direction relative to the longitudinal direction of the second conductor, and
depositing a second portion of the first conductor on the substrate in a left-to- right direction relative to the longitudinal direction of the second conductor.

12. The method according to claim 11, further comprising depositing the first conductor and the second conductor using the evaporation mask suspended above the substrate.

13. The method according to claim 12, wherein depositing the first conductor and the second conductor further comprises projecting a shadow image of the evaporation mask to deposit the first conductor and the second conductor on the substrate.

14. The method according to claim 10, further comprising fabricating the Josephson Junction by:
arranging a first conductor on the substrate;
depositing a second conductor having a first portion and a second portion on the substrate; and
arranging a dielectric layer between the first conductor and the second conductor,
wherein the first portion and the second portion of the second conductor are each deposited on the substrate at a different distance from the first conductor.

15. The method according to claim 14, wherein a distance between the first conductor and the first portion of the second conductor is less than a distance between the first conductor and the portion of the second conductor.

16. The method of claim 11, wherein the first conductor and the second conductor are constructed of aluminium deposited on the substrate at different angles.

17. The method of claim 10, wherein the three layers of material of the triple stack configuration arranged on the substrate comprise resists and/or an inorganic layer.

18. The method of claim 10, further comprising arranging four Dolan bridges side by side to create a plurality of Josephson Junctions.

19. A method of manufacturing an asymmetric Double Dolan bridge, the method comprising:
depositing three layers of material on a substrate with an evaporation mask suspended above the substrate;
depositing a first conductor and a second conductor on the substrate to form quadrupole qubit;
wherein depositing the first conductor on the substate comprises applying a first portion of the first conductor on the substrate in a left-to-right direction, and applying a second portion of the first conductor on the subject in a right-to-left direction.

20. The method according to claim 19, further comprising arranging the first conductor and the second conductor into an asymmetrical junction including the first portion of the first conductor, the second portion of the first conductor, and the second conductor, by stacking no more than the second conductor and one of the first portion of the first conductor or the second portion of the first conductor.
